(19) United States
(12) Patent Application Publication
(10) Pub. No.: US 2025/0107064 A1
(43) Pub. Date: Mar. 27, 2025

(54) A Memory Device Comprising an Electrically Floating Body Transistor

(71) Applicant: Zeno Semiconductor, Inc., Sunnyvale, CA (US)

(72) Inventors: Yuniarto Widjaja, Cupertino, CA (US); Jin-Woo Han, San Jose, CA (US)

(73) Assignee: Zeno Semiconductor, Inc., Sunnyvale, CA (US)

(21) Appl. No.: 18/727,288

(22) PCT Filed: Jan. 9, 2023
(86) PCT No.: PCT/US2023/010379

§ 371 Date: Jul. 8, 2024

Related U.S. Application Data
(60) Provisional application No. 63/298,211, filed on Jan. 10, 2022.

(51) Int. Cl. H10B 12/00; H10D 30/00; H10D 30/40; H10D 30/47; H10D 30/67; H10D 30/68; H10D 30/69; H10D 62/10

(52) U.S. Cl. CPC H10B 12/20; H10D 30/40; H10D 30/47; H10D 30/501; H10D 30/6735; H10D 30/689; H10D 30/711; H10D 62/121

(57) ABSTRACT

A semiconductor memory cell includes a floating body region configured to be charged to a level indicative of a state of the memory cell. The floating body region is surrounded on all sides by gate region and may include a nanosheet FET, a multi-bridge-channel (MBC) FET, a nanoribbon FET or a nanowire FET. The floating body region is configured to have at least first and second stable states.

### FIELD OF THE INVENTION

The present invention relates to semiconductor memory technology. More specifically, the present invention relates to a semiconductor memory device comprising of an electrically floating body transistor.

### BACKGROUND OF THE INVENTION

Semiconductor memory devices are used extensively to store data. Memory devices can be characterized according to two general types: volatile and non-volatile. Volatile memory devices such as static random access memory (SRAM) and dynamic random access memory (DRAM) lose data that is stored therein when power is not continuously supplied thereto.

A DRAM cell without a capacitor has been investigated previously. Such memory eliminates the capacitor used in the conventional 1T/1C memory cell, and thus is easier to scale to smaller feature size. In addition, such memory allows for a smaller cell size compared to the conventional 1T/1C memory cell. Chatterjee et al. have proposed a Taper Isolated DRAM cell concept in “Taper Isolated Dynamic Gain RAM Cell”, P. K. Chatterjee et al., pp. 698-699, International Electron Devices Meeting, 1978 (“Chatterjee-1”), “Circuit Optimization of the Taper Isolated Dynamic Gain RAM Cell for VLSI Memories”, P. K. Chatterjee et al., pp. 22-23, IEEE International Solid-State Circuits Conference, February 1979 (“Chatterjee-2”), and “dRAM Design Using the Taper-Isolated Dynamic RAM Cell”, J. E. Leiss et al., pp. 337-344, IEEE Journal of Solid-State Circuits, vol. SC-17, no. 2, April 1982 (“Leiss”), all of which are hereby incorporated herein, in their entireties, by reference thereto. The holes are stored in a local potential minimum, which looks like a bowling alley, where a potential barrier for stored holes is provided. The channel region of the Taper Isolated DRAM cell contains a deep n-type implant and a shallow p-type implant. As shown in “A Survey of High-Density Dynamic RAM Cell Concepts”, P. K. Chatterjee et al., pp. 827-839, IEEE Transactions on Electron Devices, vol. ED-26, no. 6, June 1979 (“Chatterjee-3”), which is hereby incorporated herein, in its entirety, by reference thereto, the deep n-type implant isolates the shallow p-type implant and connects the n-type source and drain regions.

Terada et al. have proposed a Capacitance Coupling (CC) cell in “A New VLSI Memory Cell Using Capacitance Coupling (CC) Cell”, K. Terada et al., pp. 1319-1324, IEEE Transactions on Electron Devices, vol. ED-31, no. 9, September 1984 (“Terada”), while Erb has proposed Stratified Charge Memory in “Stratified Charge Memory”, D. M. Erb, pp. 24-25, IEEE International Solid-State Circuits Conference, February 1978 (“Erb”), both of which are hereby incorporated herein, in their entireties, by reference thereto.

DRAM based on the electrically floating body effect has been proposed both in silicon-on-insulator (SOI) substrate (see for example “The Multistable Charge-Controlled Memory Effect in SOI Transistors at Low Temperatures”, Tack et al., pp. 1373-1382, IEEE Transactions on Electron Devices, vol. 37, May 1990 (“Tack”), “A Capacitor-less 1T-DRAM Cell”, S. Okhonin et al., pp. 85-87, IEEE Electron Device Letters, vol. 23, no. 2, February 2002 and “Memory Design Using One-Transistor Gain Cell on SOI”, T. Ohsawa et al., pp. 152-153, Tech. Digest, 2002 IEEE International Solid-State Circuits Conference, February 2002, all of which are hereby incorporated herein, in their entireties, by reference thereto) and in bulk silicon (see for example “A one transistor cell on bulk substrate (1T-Bulk) for low-cost and high density eDRAM”, R. Ranica et al., pp. 128-129, Digest of Technical Papers, 2004 Symposium on VLSI Technology, June 2004 (“Ranica-1”), “Scaled 1T-Bulk Devices Built with CMOS 90 nm Technology for Low-Cost eDRAM Applications”, R. Ranica et al., 2005 Symposium on VLSI Technology, Digest of Technical Papers (“Ranica-2”), “Further Insight Into the Physics and Modeling of Floating-Body Capacitorless DRAMs”, A. Villaret et al, pp. 2447-2454, IEEE Transactions on Electron Devices, vol. 52, no. 11, November 2005 (“Villaret”), “Simulation of intrinsic bipolar transistor mechanisms for future capacitor-less eDRAM on bulk substrate”, R. Pulicani et al., pp. 966-969, 2010 17th IEEE International Conference on Electronics, Circuits, and Systems (ICECS) (“Pulicani”), all of which are hereby incorporated herein, in their entireties, by reference thereto).

Widjaja and Or-Bach describes a bi-stable SRAM cell incorporating a floating body transistor, where more than one stable state exists for each memory cell (for example as described in U.S. Pat. No. 8,130,548 to Widjaja et al., titled “Semiconductor Memory Having Floating Body Transistor and Method of Operating” (“Widjaja-1”), U.S. Pat. No. 8,077,536, “Method of Operating Semiconductor Memory Device with Floating Body Transistor Using Silicon Controlled Rectifier Principle” (“Widjaja-2”), U.S. Pat. No. 9,230,651, “Memory Device Having Electrically Floating Body Transistor” (“Widjaja-3”), all of which are hereby incorporated herein, in their entireties, by reference thereto). This bi-stability is achieved due to the applied back bias which causes impact ionization and generates holes to compensate for the charge leakage current and recombination.

### SUMMARY OF THE INVENTION

A semiconductor memory cell comprising an electrically floating body having two stable states is disclosed. A method of operating the memory cell is disclosed.

According to an aspect of the present invention, a semiconductor memory cell includes: a floating body region configured to be charged to a level indicative of a state of the memory cell; a first region in electrical contact with said floating body region; a second region in electrical contact with the floating body region and spaced apart from the first region; a gate positioned between the first and second regions; wherein the gate surrounds the floating body region on all sides; a buried well layer in electrical contact with a portion of the floating body region; and a substrate underlying the floating body region and the first and second regions; wherein the floating body region is configured to have at least first and second stable states; wherein an amount of cell current from the first region to the second region when the floating body region is in the first stable state is higher than an amount of cell current from the first region to the second region when the floating body region is in the second stable state.

In at least one embodiment, the floating body region comprises a nanosheet FET, a multi-bridge-channel (MBC) FET, a nanoribbon FET or a nanowire FET.

In at least one embodiment, the floating body region is oriented vertically.

In at least one embodiment, the memory cell comprises a FinFET memory cell or an FD-SOI memory cell.

In at least one embodiment, a conduction pathway for current flow through the floating body region between the first and second regions is larger when the floating body region is in the first stable state than when the floating body region is in the second stable state.

In at least one embodiment, a number of conduction channels for current flow through the floating body region between the first and second regions when the floating body region is in the first stable state is greater than a number of conduction channels for current flow through the floating body region between the first and second regions when the floating body region is in the second stable state.

According to an aspect of the present invention, a semiconductor memory array includes: a plurality of semiconductor memory cells as described above, arranged in a matrix of rows and columns.

According to an aspect of the present invention, a method of operating a semiconductor memory cell having a floating body region configured to be charged to a level indicative of a state of the memory cell; a first region in electrical contact with the floating body region; a second region in electrical contact with the floating body region and spaced apart from the first region; a buried well layer in electrical contact with a portion of the floating body region; a gate positioned between the first and second regions; wherein the gate surrounds the floating body region on all sides; and a substrate underlying the floating body region and the first and second regions; the method including: operating the semiconductor memory cell with the floating body region in a first stable state; and operating the semiconductor memory cell with the floating body region in a second stable state; wherein an amount of cell current from the first region to the second region when the floating body region is in the first stable state is higher than an amount of cell current from the first region to the second region when the floating body region is in the second stable state.

In at least one embodiment, the floating body region comprises a nanosheet FET, a multi-bridge-channel (MBC) FET, a nanoribbon FET or a nanowire FET.

In at least one embodiment, the floating body region is oriented vertically.

In at least one embodiment, the memory cell comprises a FinFET memory cell or an FD-SOI memory cell.

In at least one embodiment, a conduction pathway for current flow through the floating body region between the first and second regions is larger when the floating body region is in the first stable state than when the floating body region is in the second stable state.

In at least one embodiment, a number of conduction channels for current flow through the floating body region between the first and second regions when the floating body region is in the first stable state is greater than a number of conduction channels for current flow through the floating body region between the first and second regions when the floating body region is in the second stable state.

According to an aspect of the present invention, a memory cell includes: a semiconductor memory device comprising: a first floating body region configured to be charged to a level indicative of a state of the memory cell; a first region in electrical contact with the first floating body region; a second region in electrical contact with the first floating body region and spaced apart from the first region; and a first gate positioned between said first and second regions; an access device comprising: a second floating body region; a third region in electrical contact with the second floating body region; a fourth region is electrical contact with the second floating body region; and a substrate underlying the semiconductor memory device and the access device; wherein the semiconductor memory device and the access device are electrically connected in series; and wherein at least one of the first and second gate surrounds the first and second floating body regions on all sides, respectively.

In at least one embodiment, at least one of the first and second floating body regions comprises a nanosheet FET, a multi-bridge-channel (MBC) FET, a nanoribbon FET or a nanowire FET.

In at least one embodiment, at least one of the first and second floating body regions is oriented vertically.

In at least one embodiment, the first floating body region is configured to have at least first and second stable states; wherein an amount of cell current from the first region to the second region when the first floating body region is in the first stable state is higher than an amount of cell current from the first region to the second region when the first floating body region is in the second stable state.

In at least one embodiment, the second region and the third region are a common shared region.

In at least one embodiment, the first floating body region comprises multiple floating channels through which current can be selectively conducted between the first and second regions.

In at least one embodiment, the first gate has a first gate length and the second gate has a second gate length; wherein the second gate length is greater than the first gate length so that a lower impact ionization rate and lower gain of a parasitic bipolar are formed by the third region, second floating body region and fourth region than by the first region, first floating body region and the second region, so that charges are self-sustained in the first floating body region, but are not self-sustained in the second floating body region.

According to an aspect of the present invention, a semiconductor memory array, includes a plurality of semiconductor memory cells as described above, arranged in a matrix of rows and columns.

These and other advantages and features of the invention will become apparent to those persons skilled in the art upon reading the details of the embodiments as more fully described below.

### BRIEF DESCRIPTION OF THE DRAWINGS

FIG. 1 is a block diagram for a memory instance, according to an embodiment of the present invention.

FIG. 2A schematically illustrates a three-dimensional view of a known gate-all-around transistor comprising a nanosheet field-effect transistor (FET).

FIG. 2B schematically illustrates a three-dimensional view of a known gate-all-around transistor comprising a nanowire FET.

FIG. 2C schematically illustrates a three-dimensional view of a known Silicon on Insulator fin field-effect transistor (SOI FinFET).

FIG. 2D schematically illustrates a three-dimensional view of a known Fully Depleted SOI FET.

FIG. 2E schematically illustrates a cross-sectional view of a known vertical gate-all-around transistor comprising a vertical nanowire.

FIGS. 3A-3D schematically illustrate cross-sectional views of various embodiments of a memory cell according to the present invention.

FIG. 4 schematically illustrates an equivalent circuit representation of a memory array according to an embodiment of the present invention.

FIGS. 5A and 5B schematically illustrate an equivalent circuit representation of a memory array and a cross-sectional view of a memory cell, respectively, for hold operation according to an embodiment of the present invention.

FIG. 6 is an equivalent circuit representation of a portion of a memory cell formed by the source region, floating body region, and the drain region, according to an embodiment of the present invention.

FIG. 7A shows an energy band diagram characterizing an intrinsic bipolar device when a floating body region is positively charged and a positive bias is applied to a bit line of a memory cell according to an embodiment of the present invention.

FIG. 7B shows an energy band diagram characterizing an intrinsic bipolar device when a floating body region is neutrally charged and a positive bias is applied to a bit line of a memory cell according to an embodiment of the present invention.

FIGS. 8A and 8B schematically illustrate an equivalent circuit representation of a memory array and a cross-sectional view of a memory cell, respectively, for read operation according to an embodiment of the present invention.

FIG. 9A schematically illustrates an equivalent circuit representation of a memory array and a cross-sectional view of a memory cell, respectively, for write logic-1 and logic-0 operations according to an embodiment of the present invention.

FIGS. 9B and 9C schematically illustrate cross-sectional views of a memory cell for write logic-1 and write logic-0 operations, respectively, according to an embodiment of the present invention.

FIG. 10A schematically illustrates a cross-sectional view of a known gate-all-around transistor which may comprise a nanosheet FET, multi-bridge-channel (MBC) FET, nanoribbon FET, or nanowire FET.

FIG. 10B schematically illustrates a memory cell comprising a nanosheet FET or multi-bridge-channel (MBC) FET or nanowire FET or nanoribbon FET according to embodiments of the present invention.

FIGS. 11A and 12A schematically illustrate a memory cell illustrated in FIG. 10B in logic-1 state and logic-0 state, respectively.

FIGS. 11B and 12B schematically illustrate energy band diagrams of the intrinsic bipolar device of the memory cell illustrated in FIG. 10B, when the memory cell is in logic-1 state and logic-0 state, respectively.

### DETAILED DESCRIPTION OF THE INVENTION

Before the present memory cells, memory arrays and devices are described, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are now described. All publications mentioned herein are incorporated herein by reference to disclose and describe the methods and/or materials in connection with which the publications are cited.

It must be noted that as used herein and in the appended claims, the singular forms “a”, “an”, and “the” include plural referents unless the context clearly dictates otherwise. Thus, for example, reference to “a cell” includes a plurality of such cells and reference to “the floating body” includes reference to one or more floating bodies and equivalents thereof known to those skilled in the art, and so forth.

The publications discussed herein are provided solely for their disclosure prior to the filing date of the present application. The dates of publication provided may be different from the actual publication dates which may need to be independently confirmed.

### Definitions

A “conduction channel” as used herein, refers to the region between the source and drain regions of a transistor that is electrically controlled by the gate. For n-type transistor (NFET), a positive gate voltage, higher than a threshold voltage, will make the channel region conductive and turn on the transistor, and vice versa for the p-type transistor (PFET).

A “floating channel” or “floating conduction channel” as used herein, refers to a conduction channel that is not electrically connected to a terminal or a control line.

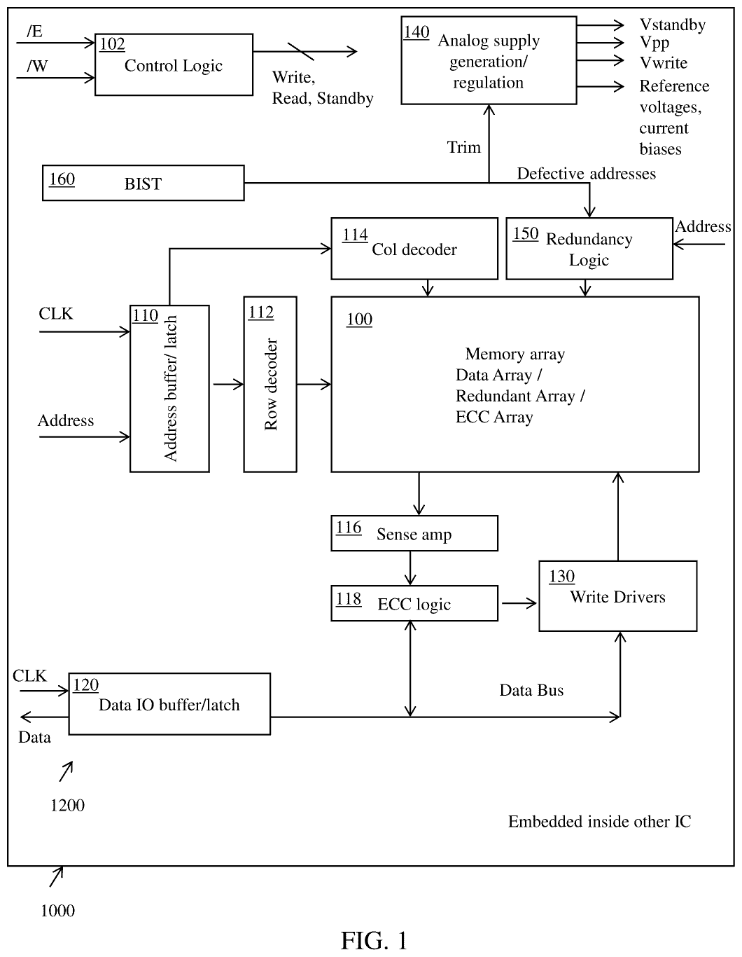

FIG. 1 illustrates a memory instance 1200, comprising of memory array 100 and periphery circuitries associated with the memory array 100. Examples of the periphery circuitries are shown in FIG. 1: control logic 102 which receives for example enable (/E) and write (/W) signals and controls the operation of the memory array; address buffer 110, which transmits the address received to row decoder 112 and column decoder 114; reading circuitry such as sense amplifier 116 and error correction circuit (ECC) 118; data buffer 120, which outputs the read data or transmits the write data into write drivers 130; analog supply generators and/or regulators 140 which provides additional voltage levels needed for the memory array operation; redundancy logic 150 which may be used to increase the yield of the memory instance; built-in-self-test (BIST) 160 which may be used to set the trim levels for the supply generators 140 and/or replace the defective units with redundant array. The BIST may sense the chip temperature and trim the voltage levels of the supply generator according to the temperature. The memory instance 1200 may be a discrete memory component or it may be embedded inside another integrated circuit device 1000.

A memory cell according to the present invention is a type of transistor featuring a floating body. The floating body device could be manifested to various device types such as gate-all-around transistors, wherein a gate surrounds the floating body region on all sides, and which may comprise nanowire FET, multi-bridge-channel (MBC) FET, nanosheet FET, nanoribbon FET, fully depleted silicon-on-insulator (FD-SOI), FinFET, multi-gate FET.

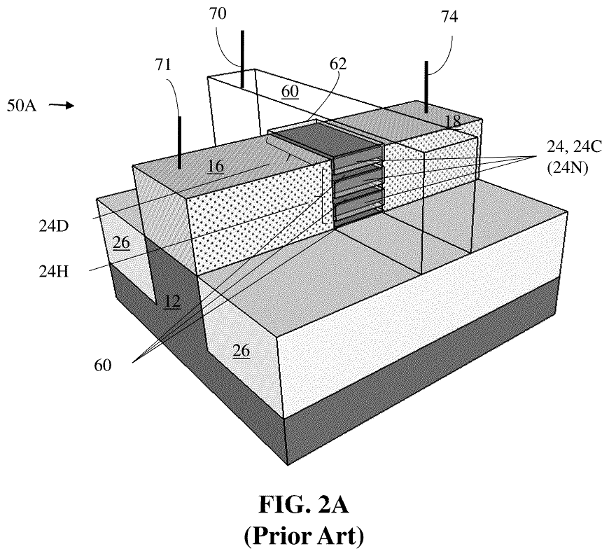

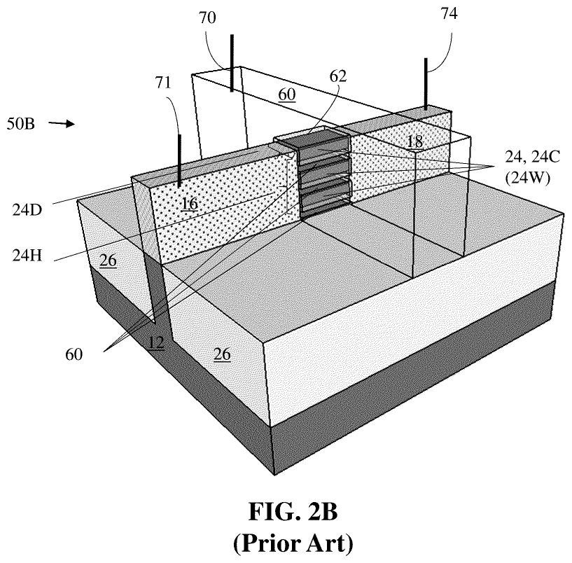

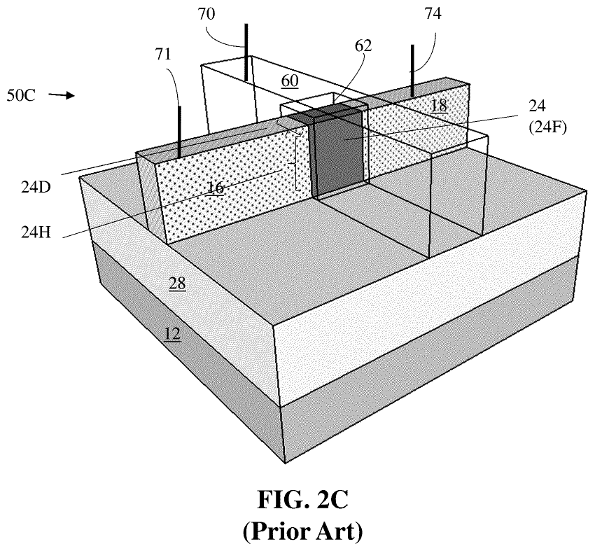

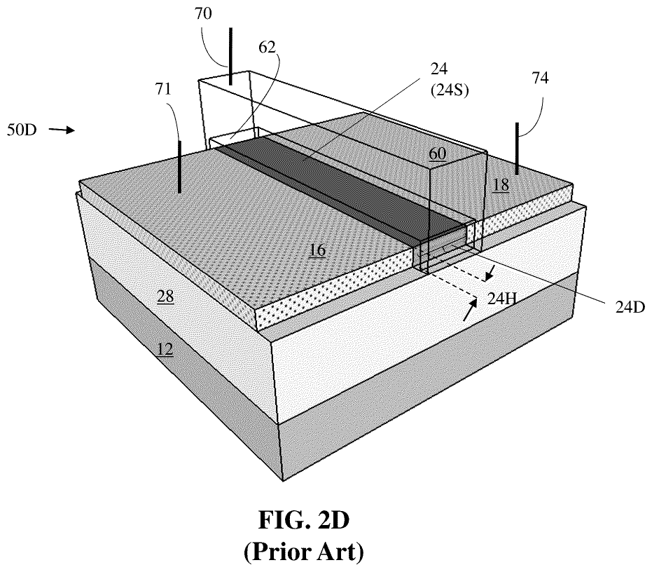

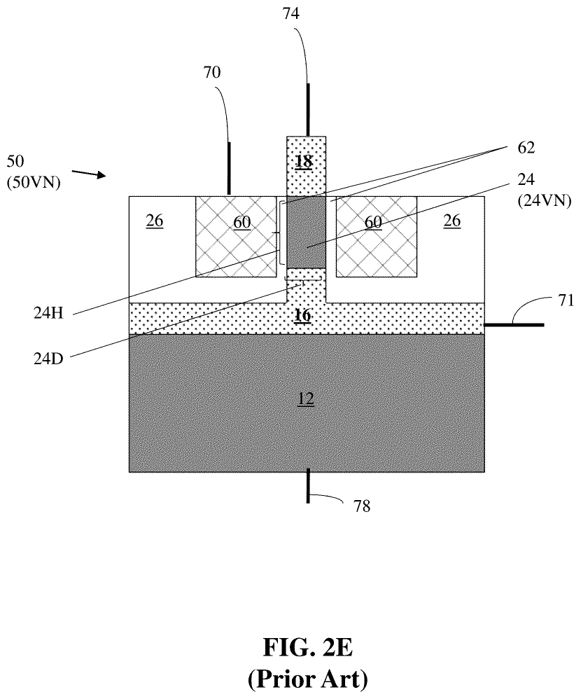

FIGS. 2A-2B each show a transistor 50 (50A, 50B) based on a gate-all-around structure, where the gate region surrounds the conduction channel region on all sides. The transistor 50A shown in FIG. 2A can be referred to as a multi-bridge-channel type FET, such as presented in U.S. Pat. No. 7,229,884 B2 or a nanosheet transistor, such as presented in U.S. Pat. No. 10,535,733 B2, both of which are incorporated herein, in their entireties, by reference thereto. The transistor 50B shown in FIG. 2B can be referred to as a nanoribbon transistor, such as presented in U.S. Pat. No. 10,388,733 B2 or as a nanowire transistor, such as presented in U.S. Pat. No. 9,991,261 B2, both of which are incorporated herein, in their entireties, by reference thereto. The gate-all-around device structures shown in FIGS. 2A and 2B have at least one suspended semiconductor channel fully surrounded by a gate. FIGS. 2C-2D show transistors 50 (50C-50D, respectively) fabricated on a silicon-on-insulator (SOI) wafer. The transistor 50C shown in FIG. 2C can be referred to a fin field effect transistor or FinFET, such as presented in U.S. Pat. No. 6,413,802 B1, which is hereby incorporated herein, in its entirety, by reference thereto. The transistor 50D shown in FIG. 2D can be referred to a fully-depleted SOI transistor, such as presented in U.S. Pat. No. 8,030,145 B2, which is hereby incorporated herein, in its entirety, by reference thereto. The SOI transistors shown in FIGS. 2C and 2D have a silicon channel overlaid on the buried oxide. The common feature of the transistors 50 is an electrically floating body without direct body contact. The floating body devices shown in FIGS. 2A-2D are representative examples but the invention is not limited to these examples. Rather, it should be understood that the memory operation presented in this invention could be applied to variations of those floating body transistors.

Referring to the gate-all-around structures shown in FIGS. 2A and 2B, the device structures share various similarities except for the aspect ratios of the floating body regions 24 (24N, 24W). In the transistor 50A having a nanosheet (or nanobridge) floating body region 24 (i.e., see 24N in FIG. 2A), the width 24D of the nanosheet 24N is substantially greater than the height 24H of the nanosheet 24N. In the transistor 50B having a nanowire 24W (or nanoribbon), the width 24D of the nanowire 24W is substantially similar to the height 24H of the nanowire 24W (or nanoribbon). Alternatively, the cross-section of the nanowire 24W may be circular. In the gate-all-around structures shown in FIGS. 2A and 2B, transistor 50 (50A, 50B) includes a substrate 12. Substrate 12 is typically made of silicon, but may also comprise, for example, germanium, silicon germanium, gallium arsenide, carbon nanotubes, and/or other semiconductor materials. In some embodiments of the invention, substrate 12 can be the bulk material of the semiconductor wafer. Transistor 50 also includes a floating body region 24 (24N, 24W). The floating body region 24 may be grown epitaxially on top of substrate 12. The floating body region 24 is typically made of silicon, but may also comprise, for example, germanium, silicon germanium, gallium arsenide, carbon nanotubes, and/or other semiconductor materials. The floating body region 24 is bounded by source region 16, drain region 18, and surrounded by gate insulating layer 62. The gate-all-around transistor 50 is isolated from adjacent transistors 50 by insulating layer 26. Insulating layers 26 (like, for example, shallow trench isolation (STI)), may be made of silicon oxide, for example, though other insulating materials may be used. In the embodiments shown in FIGS. 2A-2B, the gate-all-around transistors 50 each have three floating channels 24C (i.e. nanosheet 24N floating channels 24C in FIG. 2A and nanowire 24W floating channels 24C in FIG. 2B). However, in each embodiment, the number of floating channels 24C is not limited to three but could vary (e.g., 1, 2, 4, 5 or more). A gate 60 is positioned in between the source region 16 and the drain region 18, surrounding the floating body region 24 on all sides. The gate 60 is insulated from the floating body region 24 by an insulating layer 62. Insulating layer 62 may be made of silicon oxide and/or other dielectric materials, including high-K dielectric materials, such as, but not limited to, tantalum peroxide, titanium oxide, zirconium oxide, hafnium oxide, and/or aluminum oxide. The gate 60 may be made of, for example, polysilicon material or metal gate electrode, such as tungsten, tantalum, titanium and their nitrides.

The transistors 50 (50A, 50B, 50C, 50D, 50VN) as shown in FIGS. 2A-2E include various control lines. The source region 16 is connected to source line (SL) terminal 71, the drain region 18 is connected to bit line terminal (BL) 74, and the gate region 60 is connected to the word line (WL) terminal 70. FIG. 2E shows substrate (SUB) terminal 78 connected to substrate 12.

Referring to the transistors 50 (50C, 50D) having SOI device structures, as shown in FIGS. 2C and 2D, the device structures share various similarities except for the aspect ratios of the floating body region 24. In the FinFET (or multi-gate) transistor 50C, the height 24H of the floating body 24 (24F) (or fin) is substantially greater than the width 24D of the floating body 24F. In the FD-SOI transistor 50D, the width 24D of the floating body 24 (24S) is substantially greater than the height 24H. In the SOI device structure shown in FIGS. 2C and 2D, transistor 50 (50C, 50D) includes a substrate 12. Substrate 12 is typically made of silicon, but may also comprise, for example, germanium, silicon germanium, gallium arsenide, carbon nanotubes, and/or other semiconductor materials. In some embodiments of the invention, substrate 12 can be the bulk material of the semiconductor wafer. Transistor 50 (50C, 50D) also includes a floating body region 24 (24F, 24S). The floating body region 24 is typically made of silicon, but may also comprise, for example, germanium, silicon germanium, gallium arsenide, carbon nanotubes, and/or other semiconductor materials. The floating body region 24 is bounded on by source region 16, drain region 18, gate insulating layer 62, and buried oxide (BOX) layer 28. The SOI-based transistor 50 (50C, 50D) is isolated from adjacent transistors 50 by BOX layer 28. The BOX layer 28 may be made of silicon oxide, for example, though other insulating materials may be used. A gate 60 is positioned in between the source region 16 and the drain region 18. Gate 60 surrounds three sides of floating fin 24F in FIG. 2C and floating body region 24S of the FD-SOI transistor 50D in FIG. 2D. The gate 60 is insulated from the floating body region 24 (24F, 24S) by an insulating layer 62. Insulating layer 62 may be made of silicon oxide and/or other dielectric materials, including high-K dielectric materials, such as, but not limited to, tantalum peroxide, titanium oxide, zirconium oxide, hafnium oxide, and/or aluminum oxide. The gate 60 may be made of, for example, polysilicon material or metal gate electrode, such as tungsten, tantalum, titanium and their nitrides.

FIG. 2E illustrates transistor 50 (50VN) comprising a vertical nanowire gate-all-around transistor, for example as described in “Vertical Silicon-Nanowire Formation and Gate-All-Around MOSFET”, B. Yang, et. al., pp. 791-794, IEEE Electron Device Letters, vol. 29, no. 7, July 2008, which is incorporated herein, in its entirety, by reference thereto. In the vertical gate-all-around transistor, the channel region, which is the floating body region 24 (24VN), is oriented vertically, with one of the source/drain region located above and the other source/drain region located below. This is in contrast to the horizontal orientation of the floating body region 24 in FIGS. 2A-2D. In FIG. 2E, the drain region 18 (connected to the BL terminal 74) is located above the floating body region 24, and the source region 16 (connected to the SL terminal 72) is located below the floating body region 24. Alternatively, the SL terminal 72 may be connected to the drain region 18 above the floating body region 24, and the BL terminal 74 may be connected to the source region 16 below the floating body region 24. In the vertical gate-all-around transistor, the height 24H of the floating body 24 (24VN) is greater than the width 24D. The gate region 60 surrounds the floating body region 24.

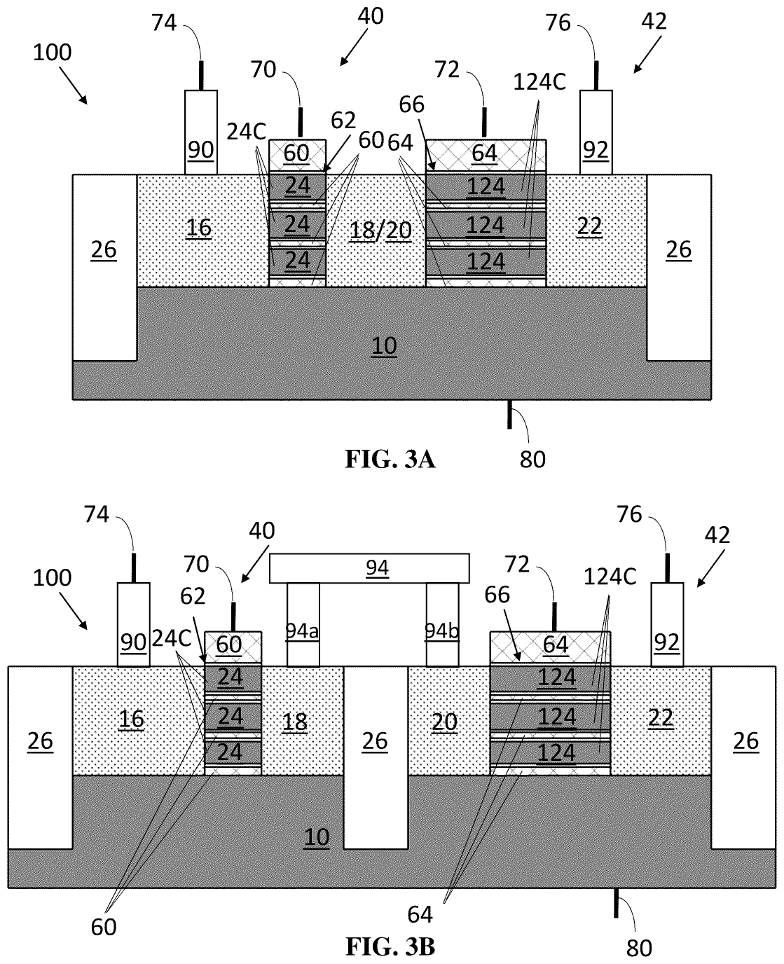

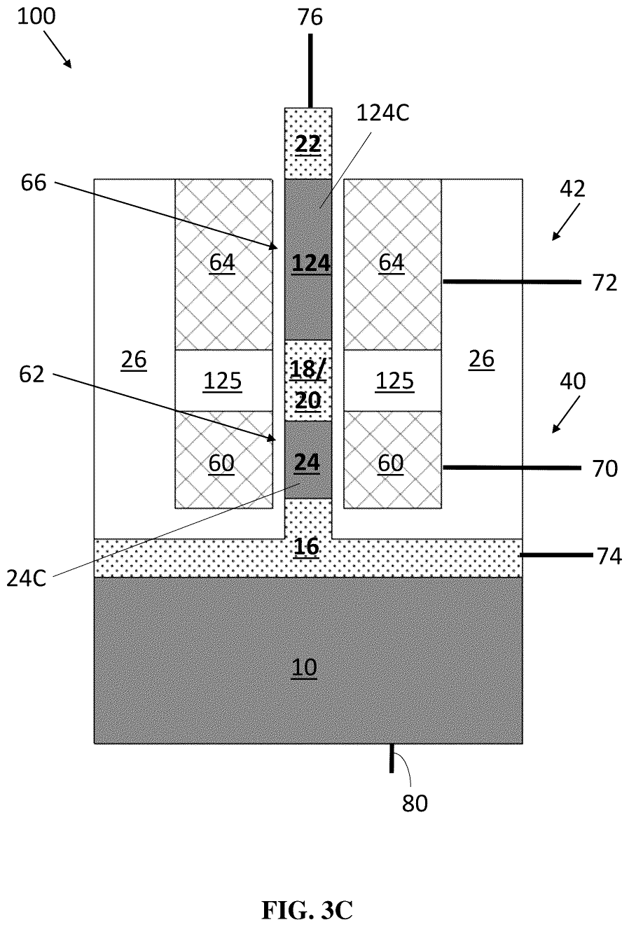

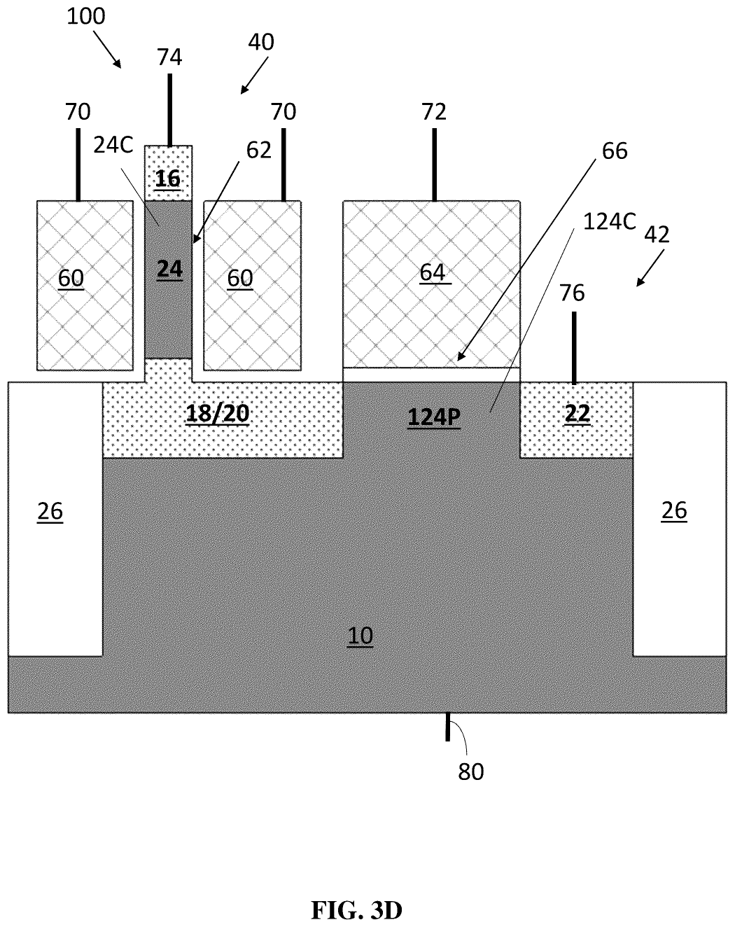

FIGS. 3A-3D schematically illustrate cross-sectional views of a memory cell 100 according to various embodiments of the present invention. Memory cell 100 includes memory device 40 and access device 42, that are connected in series. More specifically, FIGS. 3A-3D schematically illustrate memory cells 100 with cross-sectional views taken by cuts of the cell along the direction perpendicular to the gate 60 length. While FIGS. 3A-3D show generic representations of memory cells 100 comprising a memory device 40 and access device 42 as described, it should be understood that the memory device 40 and/or access device 42 of memory cell 100 according to this invention could be replaced by a memory cell and/or access device having any of the floating body transistors exemplified in FIGS. 2A-2E. Memory device 40 functions to store the state of the memory cell 100, and is accessed through the access device 42.

FIG. 3A shows a memory cell 100 sharing the drain region 18 of the memory device 40 and the source region 20 of the access device 42.

FIG. 3B shows a memory cell 100 with drain region 18 of the memory device 40 and the source region 20 of the access device 42 separated by the insulating layer 26 but connected through conductive elements 94, 94a, and 94b.

FIG. 3C shows a memory cell 100 based on the vertical nanowire gate all around transistor described in FIG. 2E where the drain region 18 of the memory device 40 and the source region 20 of the access device 42 are shared. As the vertical nanowire gate all around transistors for the memory device 40 and the access device 42 are vertically stacked, the gate regions 60 and 64 are separated by inter-gate dielectric layer 125.

FIG. 3D shows a memory cell 100 of a hybrid type having hybrid device types. The memory device 40 comprises a vertical nanowire gate all around transistor as described in FIG. 2E, for example, and an access device 42 having a bulk planar type transistor. Although the drain region 18 of the memory device 40 and the source region 20 of the access device 42 are shown as being shared in FIG. 3D, the drain region 18 and the source region 20 could alternatively be separately formed and then connected through a conductor similar to the style illustrated in FIG. 3B.

The conductivity type of the access device 42 may be the same as or different from (e.g., the opposite of) the conductivity type of the memory device 40.

The access device 42 may have similar structure to that of any of the transistors shown in FIGS. 2A-2E. As shown in FIGS. 3A-3D, the memory device 40 and the access device 42 share a substrate 10. The access device 42 also includes floating body region 124. The floating body region 124 could be grown epitaxially on top of substrate 10. The floating body region 124 is typically made of silicon, but may also comprise, for example, germanium, silicon germanium, gallium arsenide, carbon nanotubes, and/or other semiconductor materials. The floating body region 124 is bounded by source region 20, drain region 22, and gate insulating layer 66. The memory cell 100 is isolated from adjacent memory cells 100 by insulating layers 26. Insulating layers 26 (like, for example, shallow trench isolation (STI)), may be made of silicon oxide, for example, although other insulating materials may be used.

FIGS. 3A and 3B show that the gate-all-around memory cell 100 has a memory cell 40 having a floating body 24 that includes three floating channels 24C (i.e. nanosheet or nanowire) but the number of floating channels 24 could vary, as noted above. Similarly, access device 42 in FIGS. 3A and 3B have a floating body 124 that includes three floating channels 124C (i.e. nanosheet or nanowire) but the number of floating channels 124 could vary. The number of floating channels 24C in the memory cell 40 may or may not be the same as the number of floating channels 124C in the access device 42. FIG. 3C shows the floating channel 124 having a vertical orientation, and FIG. 3D shows the channel 124P of the access device 42 being electrically connected to the substrate region 10, and therefore is not floating. A gate 64 is positioned in between the source region 20 and the drain region 22, and on the floating body region 124. The gate 64 is insulated from the floating body region 124 by an insulating layer 66. Insulating layer 66 may be made of silicon oxide and/or other dielectric materials, including high-K dielectric materials, such as, but not limited to, tantalum peroxide, titanium oxide, zirconium oxide, hafnium oxide, and/or aluminum oxide. The gate 64 may be made of, for example, polysilicon material or metal gate electrode, such as tungsten, tantalum, titanium and their nitrides.

For simplicity, the conductivity type of both memory device 40 and the access device 42 will be described as n-channel type. However, an access device 42 with p-channel type and a memory device 40 with n-channel type could be alternatively provided. Further alternatively, both memory device 40 and access device 42 may be provided as a p-channel type, or access device 42 may be provided as n-channel type and memory device 40 may be provided as p-channel type. Furthermore, the length of gate 64 of the access device 42 may be longer than the length of gate 60 of the memory device 40. The provision of a gate length of gate 64 as longer than a gate length of gate 60 results in lower impact ionization rate and lower gain of the parasitic bipolar of the access device 42 formed by source 20-floating body 124-drain 22, compared to the parasitic bipolar of the memory device 40 formed by source 16-floating body 24-drain 18. Therefore, while the charges are self-sustained in the floating body region 24 of the memory device 40, the charges are not self-sustained in the floating body region 124 of the access device 42.

Memory cell 100 may include various control lines. In some embodiments, conductive element 90 (FIGS. 3A and 3B) connects the source region 16 of the floating body transistor 40 to the bit line (BL) terminal 74, while conductive element 92 connects the drain region 22 of the access transistor 42 to the ground line (GL) terminal 76. Alternatively, the source region 16 of the floating body transistor 40 may be connected to the GL terminal 76, and the drain region of the access transistor 42 may be connected to the BL terminal 74. The conductive elements 90, 92, 94, 94a, and 94b may be formed of, but not limited to, tungsten or silicided silicon. In other embodiments, bit line (BL) terminal 74 can be directly connected to source region 16, e.g., see FIGS. 3C and 3D. Also, ground line (GL) terminal 76 may alternatively be directly connected to the drain region 22, e.g., see FIGS. 3C and 3D. Alternatively, the source region 16 of the floating body transistor 40 may be connected to the GL terminal 76, and the drain region of the access transistor 42 may be connected to the BL terminal 74. FIG. 3C shows the access device 42 is positioned vertically above the memory device 40. Alternatively, the memory device 40 may be positioned vertically above the access device 42. In addition to the BL terminal 74 and GL terminal 76, memory cell 100 may also include word line 1 (WL1) terminal 70, which is electrically connected to the gate 60 of the memory device 40, word line 2 (WL2) terminal 72, which is electrically connected to the gate 64 of the access device 42, and substrate (SUB) terminal 80, which is connected to the substrate region 10.

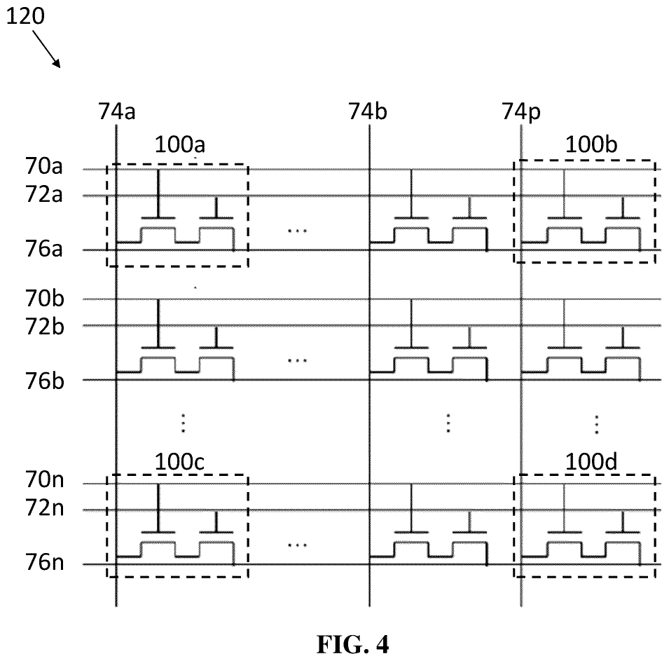

A memory array 120 comprising a plurality of the memory cells 100 (100a, 100b, 100c, 100d and other memory cells not specifically numbered) are illustrated in FIG. 4, according to an embodiment of the present invention. The memory array and operation of the memory cells 100 are described hereafter. Four exemplary instances of memory cell 100 are labeled as 100a, 100b, 100c, and 100d arranged in rows and columns. In many, but not all, of the figures where exemplary array 120 appears, representative memory cell 100a will be representative of a “selected” memory cell when the operation being described has one (or more in some embodiments) selected memory cells 100. In such figures, representative memory cell 100b will be representative of an unselected memory cell 100 sharing the same row as selected representative memory cell 100a, representative memory cell 100c will be representative of an unselected memory cell 100 sharing the same column as selected representative memory cell 100a, and representative memory cell 100d will be representative of a memory cell 100 sharing neither a row or a column with selected representative memory cell 100a.

Present in FIG. 4 are WL1 terminals 70a through 70n, WL2 terminals 72a through 72n, BL terminals 74a through 74p, and GL terminals 76a through 76n, wherein “a” represents a first terminal of a series of terminals, “b” represents a second terminal of the series, “n” represents a positive integer greater than 2, “p” represents a positive integer greater than 2, and “n” may be less than, equal to or greater than “p”. For simplicity, SUB terminal 80 is not shown in FIG. 4. Each of the WL1 70, WL2 72, and GL 76 terminals are shown associated with a single row of memory cells 100. Each of the BL terminals 74 is associated with a single column of memory cells 100. Persons of ordinary skill in the art will appreciate that many other organizations and layouts of memory array 120 are possible. For example, the source region 16 of the floating body transistor may be connected to the GL terminal 76 and the drain region 22 of the access transistor 42 may be connected to the BL terminal 74. Similarly, other terminals may be segmented or buffered, while control circuits such as word decoders, column decoders, segmentation devices, sense amplifiers, write amplifiers etc., may be arrayed around array 120 or inserted between subarrays of array 120. Thus, the exemplary embodiments, features, design options, etc., described are not limiting in this way. Several operations can be performed to memory cell 100, such as: holding, read, write logic-1 and write logic-0 operations.

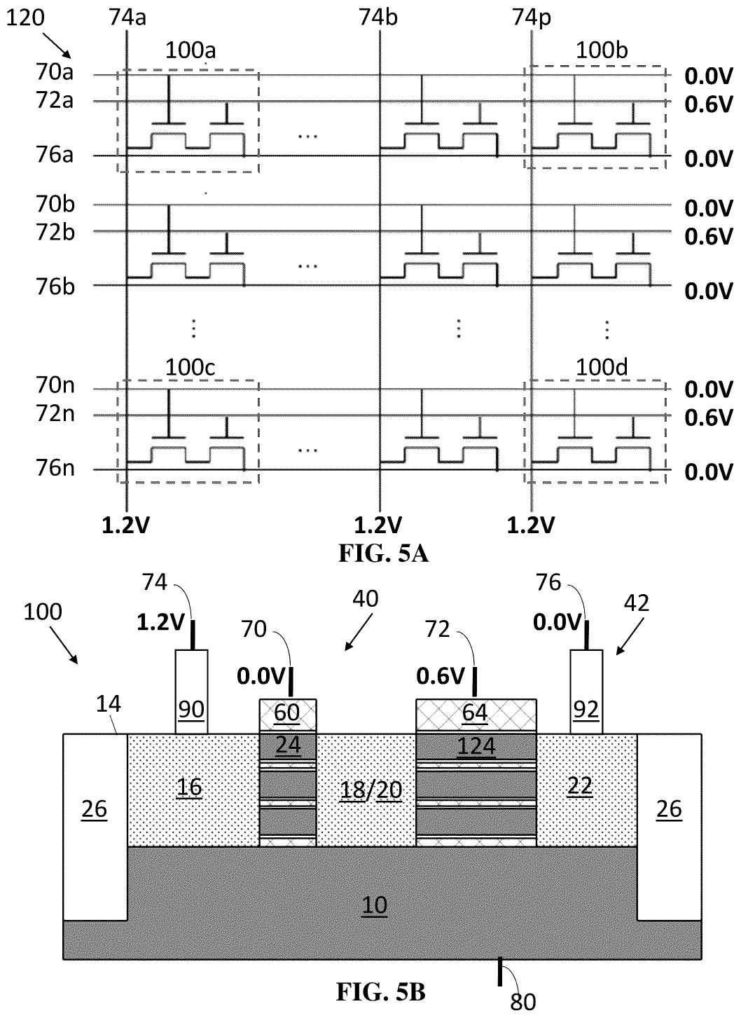

FIGS. 5A and 5B illustrate a holding operation being performed on memory array 120 and on a selected memory cell 100, respectively. Note that in FIG. 5B, the selected memory cell 100 shown could be any one of the memory cells 100a, 100b, 100c, 100d or any one of the memory cells shown in FIG. 5A that are not numbered. Further, as noted, a holding operation can be applied to the entire array 120 of memory cells 100 by applying the biases to each of the series of lines in the array by the same amounts applied to the individual lines described below with regard to FIG. 5B. Further alternatively, a holding operation can be performed on a subarray or subset of the entire number of memory cells 100 in the memory array 120 by applying the biases to only a subset of the series of lines. The holding operation can be performed by applying a positive voltage on the BL terminal 74, zero bias on GL terminal 76, a zero or low negative bias on the WL1 terminal 70 to eliminate formation of channel inversion of the floating body region 24 of the memory device 40 and near threshold voltage (threshold of gate voltage where conduction is first formed between the source and the drain) on WL2 terminal 72 to slightly but not fully turn-on the floating body region 124 of the access device 42, which allows a small amount of charge to be supplied and maintains the charge stored state of memory device 40. In one embodiment the bias conditions for the holding operation for memory cell 100 are: 0.0 volt is applied to WL1 terminal 70, +0.6 volt is applied to WL2 terminal 72, +1.2 volt is applied to BL terminal 74, 0.0 volt is applied to GL terminal 76, and 0.0 volt is applied to the SUB terminal 80. In other embodiments, different voltages may be applied to the various terminals of memory cell 100 as a matter of design choice and the exemplary voltages described are not limiting in any way.

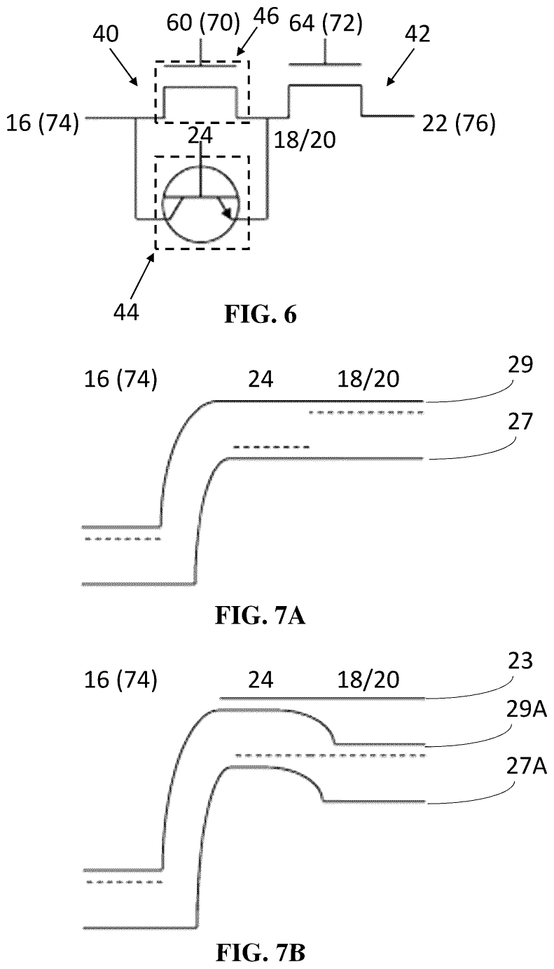

FIG. 6 illustrates an equivalent circuit representation of a memory cell 100 showing the memory device 40, formed by the drain region 16, source region 18 and the gate 60 and access device 42, formed by the drain region 20, source region 22, and the gate 64, connected in series. Terminals 74, 70, 72 and 76 are shown in parentheses next to the elements 16, 60, 64 and 22 that they are electrically connected to, respectively. Inherent in the memory device 40 are inherent metal-oxide-semiconductor (MOS) device 46 and bipolar device 44 formed by the source region 16, floating body 24, and the drain region 18.

FIG. 7A shows an energy band diagram of the intrinsic bipolar device 44 when the floating body region 24 is positively charged and a positive bias is applied to the drain region 16 connected to BL terminal 74. The potential of the source region 18/20 is about zero voltage as the access device 42 is biased near-threshold voltage, where the conduction channel just started to form between the drain region 18/20 and the source region 22 of the access device 42. The dashed lines indicate the Fermi levels in the various regions of the bipolar device 44. The Fermi level is located in the band gap between the solid line 27 indicating the top of the valence band (the bottom of the band gap) and the solid line 29 indicating the bottom of the conduction band (the top of the band gap) as is well known in the art. If floating body 24 is positively charged, a state corresponding to logic-1, the bipolar transistor 44 will be turned on as the positive charge in the floating body region 24 lowers the energy barrier of electron flow into the base region because the zero voltage of the GL terminal 76 is induced to the drain region 18 due to weakly turned-on the access device 42, with the access device 42 biased near the threshold voltage. Once the electrons are injected into the floating body region 24, the electrons will be swept into the drain region 16 due to the positive bias applied to the drain region 16. As a result of the positive bias applied to the drain region 16, the electrons are accelerated and create additional hot carriers (hot hole and hot electron pairs) through an impact ionization mechanism. The resulting hot electrons flow into the BL terminal 74 while the resulting hot holes will subsequently flow into the floating body region 24. As a result of a positive feedback mechanism, this process maintains the charge (i.e. holes) stored in the floating body region 24 which will keep the n-p-n bipolar transistor 44 on for as long as a positive bias is applied to the drain region 16 through BL terminal 74.

If floating body 24 is neutrally charged (the voltage on floating body 24 being equal to the voltage on grounded source region 18), a state corresponding to logic-0, no current will flow through bipolar transistor 44. The bipolar device 44 will remain off and no impact ionization occurs. Consequently, memory cell 100 in the logic-0 state will remain in the logic-0 state.

FIG. 7B shows an energy band diagram of the intrinsic bipolar device 44 when the floating body region 24 is neutrally charged and a positive voltage is applied to the drain region 16 connected to BL terminal 74 and the source region 18/20 at about zero voltage. In this state the energy level of the band gap bounded by solid lines 27A and 29A is different in the various regions of bipolar device 44. Because the potentials of the floating body region 24 and the source region 18/20 are equal, the Fermi levels are constant, resulting in an energy barrier between the source region 18/20 and the floating body region 24. Solid line 23 indicates, for reference purposes, the energy barrier between the source region 18/20 and the floating body region 24. The energy barrier prevents electron flow from the source region 18/20 to the floating body region 24. Thus, the bipolar device 44 will remain off.

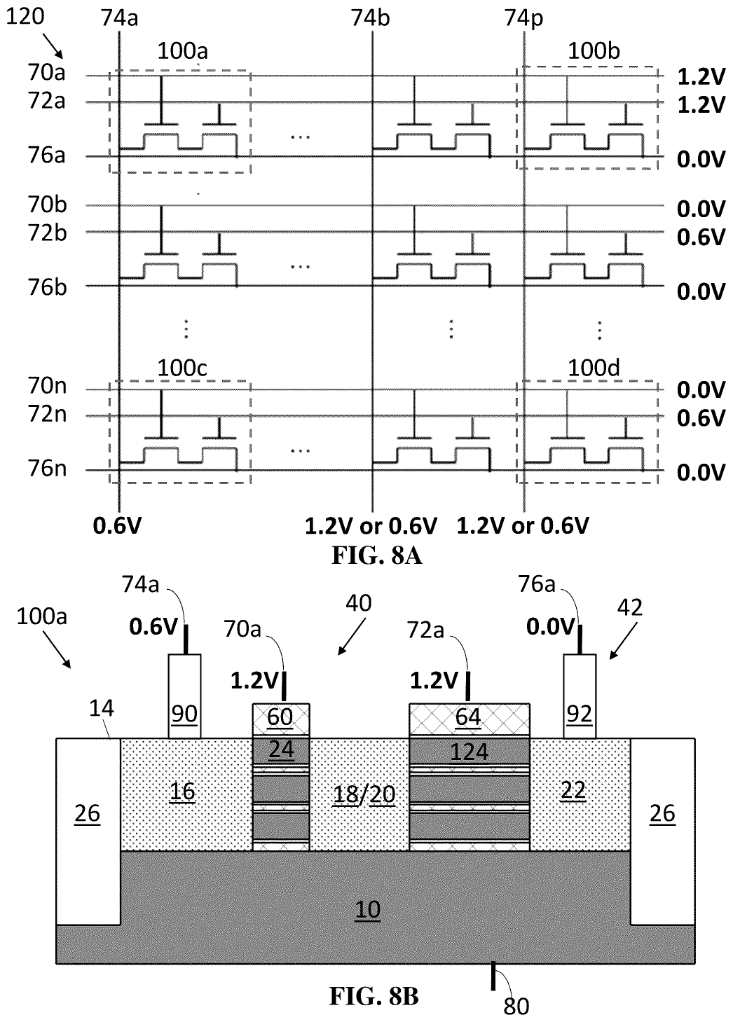

A read operation of a memory cell 100 and array 120 will be described in conjunction with FIGS. 8A and 8B. Note that in FIGS. 8A and 8B, the selected memory cell 100 upon which the read operation is being performed is memory cell 100a. Accordingly, FIG. 8B shows the biases applied to memory cell 100a. However, a read operation can be performed on any of the memory cells 100a, 100b, 100c, 100d or any one of the memory cells shown in FIG. 8A that are not numbered, by applying biases like those that are applied to memory cell 100a in FIGS. 8A and 8B. Any sensing scheme known in the art can be used with memory cell 100. The amount of charge stored in the floating body 24 can be sensed by monitoring the cell current of the memory cell 100. If memory cell 100 is in a logic-1 state having holes in the body region 24, then the memory cell 100 will have a higher cell current (e.g. current flowing from the BL terminal 74 to GL terminal 76), compared to if memory cell 100 is in a logic-0 state having no holes in floating body region 24. A sensing circuit typically connected to BL terminal 74 can then be used to determine the data state of the memory cell 100.

A read operation for example can be performed on memory cell 100 by applying the following bias conditions which are shown in FIGS. 8A-8B as applied to selected memory cell 100a. A positive voltage is applied to the selected WL2 terminal 72 (72a), which turns on the access device 42, a positive voltage is applied to the selected BL terminal 74 (74a), zero voltage is applied to the selected GL terminal 76 (76a). The positive voltage applied to the BL terminal 74 is a positive voltage that does not exceed a positive value that would causes impact ionization and change the state of the memory cell 100 from logic-0 state to logic-1 state. Zero voltage may be applied to the WL1 terminal 70. Alternatively, a positive voltage ranging from zero to +1.2 V may be applied to the WL1 terminal 70 to further enhance the current flowing through the memory cell, from the BL terminal 74 to the GL terminal 76. FIGS. 8A-8B show +1.2 V applied to WL1 terminal 70a. In one particular embodiment, +1.2 volts are applied to the WL1 terminal 70a and WL2 terminal 72a, +0.6 volt is applied to the BL terminal 74a, 0.0 volts is applied to the GL terminal 76a, and 0.0 volts is applied to the SUB terminal 80.

WL1 voltage of memory device 40 and WL2 voltage of the access device 42 of the unselected memory cells (e.g. 100c and 100d) are biased to the voltage corresponding to the hold operation condition. While a read voltage is applied to a selected BL terminal 74a, the BL disturbed half-selected memory cell 100c may experience a reduced impact ionization, which could be a condition for a change the state of the memory cell 100 from logic-1 state to logic-0 state. Typically, the lifetime of holes in the floating body region 24 (e.g. few tens of microsecond to a few second depending on the doping and defect condition) is a few orders of magnitude longer than a typical read time (e.g. from few hundreds pico-seconds to a few tens of nano-seconds), such change of the memory cell 100 is unlikely to occur. However, a maximum read time duration may be imposed as a limit in order to not change the state of the memory cells sharing the same BL as the selected memory cell.

BL voltage of memory device 100 of the unselected memory cells (e.g. 100b and 100d) are biased to the voltage corresponding to the hold operation condition such as +1.2V. While a read voltage is applied to a selected BL terminal 74a, the WL disturbed half-selected memory cell 100b may experience an impact ionization, which could be a condition to change the state of the memory cell 100 from logic-0 state to logic-1 state. The impact ionization generation time could be comparable for the time required for the read operation, which needs to be avoided. Therefore, in one embodiment of the read operation, parallel read, i.e. reading all BLs 74a-74p simultaneously, may be performed rather than a specific BL reading. FIG. 8A shows an example of the parallel read operations, where all BLs (74a, 74b, and 74p) are biased at 0.6V. The logic-0 to logic-1 disturb may also be avoided by applying a low voltage on the WL1 terminal 70a, such as 0V.

In other embodiments, different voltages may be applied to the various terminals of memory cell 100 as a matter of design choice and the exemplary voltages described are not limiting in any way.

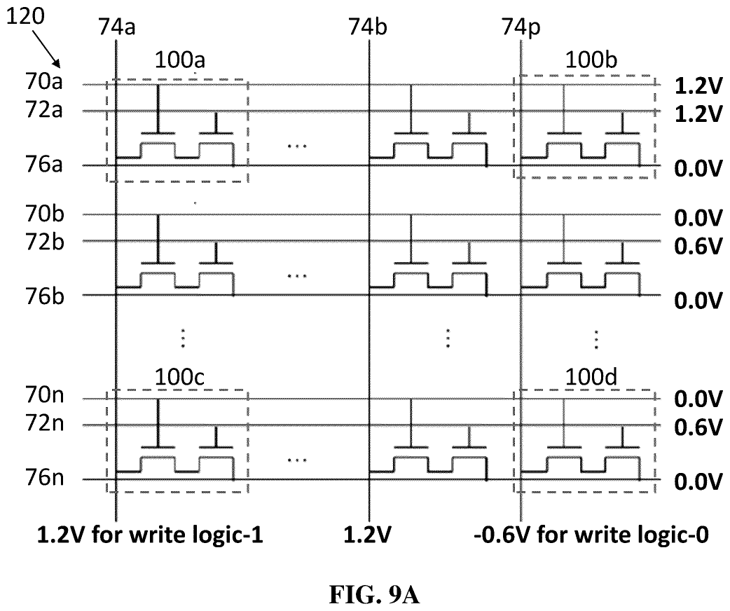

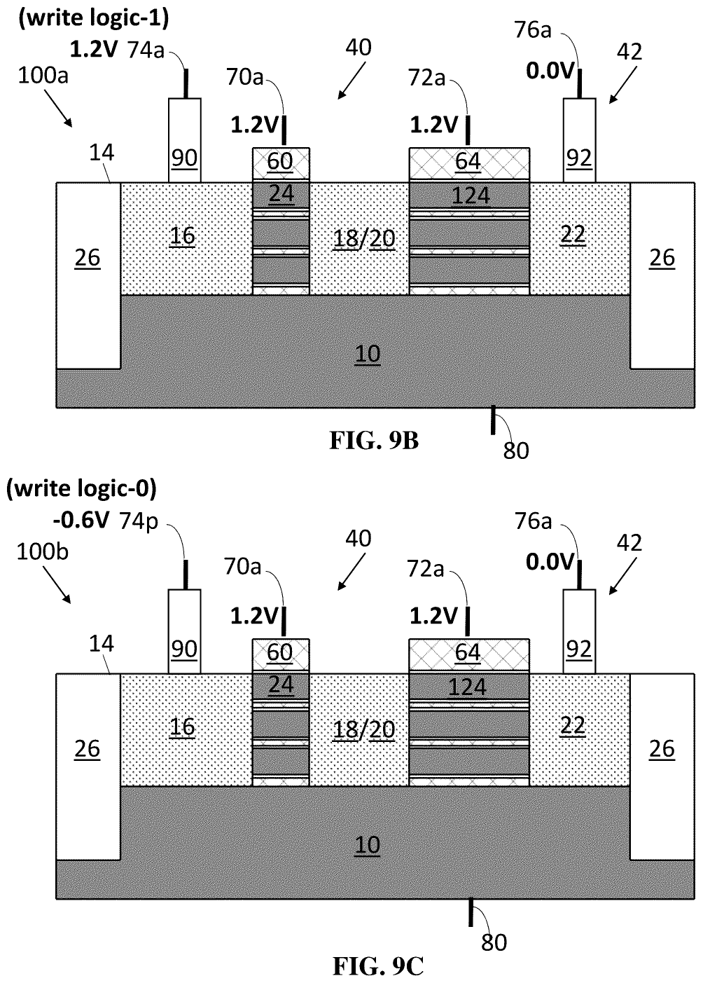

A write logic-1 or write logic-0 operation of a memory cell 100 and array 120 will be described in conjunction with FIGS. 9A-9C using an impact ionization mechanism. For exemplary purposes, the BL terminal 74a is shown as being used for a write logic-1 operation and the BL terminal 74p is shown as being used for a write logic-0 operation.

The following bias conditions are applied for a write logic-1 operation on the selected memory cell 100a. A positive voltage is applied to the WL2 terminal 72a, which turns on the access device 42, a positive voltage is applied to the BL terminal 74a, zero voltage is applied to the GL terminal 76a, and zero voltage is applied to the SUB terminal 80. A positive voltage is applied to the WL1 terminal 70a. The positive voltage applied to WL1 terminal for the write logic-1 operation is more positive than that for the holding operation. The WL1 voltage for the write logic-1 operation is set to accelerate the impact ionization for fast programming while the WL1 voltage for the hold operation is to minimally use the holding current that maintains the stored logic state. The positive voltage applied to the BL terminal 74a for the write logic-1 operation would be equal or greater than that for the holding operation in order to further accelerate the impact ionization. In one particular embodiment for write logic-1, +1.2 volts are applied to the WL1 terminal 70a and WL2a terminal 72a, +1.2 volt is applied to the BL terminal 74a, 0.0 volts is applied to the GL terminal 76a, and 0.0 volts is applied to the SUB terminal 80.

The WL1 voltage of memory device 40 and WL2 voltage of the access device 42 of the unselected memory cells (e.g. 100c) are biased to the voltage corresponding to the hold operation condition. While a write logic-1 voltage is applied to a selected BL terminal 74a, the half-selected memory cell 100c may experience a soft-impact ionization, which could be a condition to change the state of the memory cell 100c from logic-0 state to logic-1 state. However, the WL1 70n (0.0V in FIG. 9A) and WL2 72n (0.6V in FIG. 9A) voltages are set to limit the supply current for the impact ionization, so that the amount of hole generation is not sufficient to change the state of the half-selected memory cell 100c.

The following bias conditions may be applied for a write logic-0 operation, an example of which is shown as applied to memory cell 100b in FIG. 9A). A positive voltage is applied to the WL2 terminal 72a, which turns on the access device 42, a negative voltage is applied to the BL terminal 74p, zero voltage is applied to the GL terminal 76a. A positive voltage is applied to the WL1 terminal 70a. The positive voltage applied to WL1 terminal for the write logic-0 operation is more positive than that for the holding operation. The WL1 voltage for the write logic-0 operation is set to turn on the channel of the memory device 40 in order to facilitate the removal of the holes through the forward-biased pn junction current (from the floating body region 24 to the BL terminal 74p) of memory cells 100 in logic-1 state while the WL1 voltage for the hold operation is to suppress the forward junction current. The negative voltage applied to the BL terminal 74p for the write logic-0 operation is set sufficiently negative to remove the excess holes in the floating body region 24 for memory cells in a logic-1 state. In one particular embodiment for write logic-0, +1.2 volts are applied to the WL1 terminal 70a and WL2 terminal 72a, −0.6 volt is applied to the BL terminal 74p, 0.0 volts is applied to the GL terminal 76a, and 0.0 volts is applied to the SUB terminal 80.

WL1 voltage of memory device 40 and WL2 voltage of the access device 42 of the unselected memory cells (e.g. 100d) are biased to the voltage corresponding to a hold operation condition. While a write logic-0 voltage is applied to a selected BL terminal 74p, the half-selected memory cell 100d may experience a soft-forward junction current, which could be a condition to change the state of the memory cell 100 from logic-1 state to logic-0 state. However, the WL1 70n and WL2 72n voltages are set to limit the supply current for the forward junction current so that the amount of holes lost will not be sufficient to change the state of the half-selected memory cell 100d.

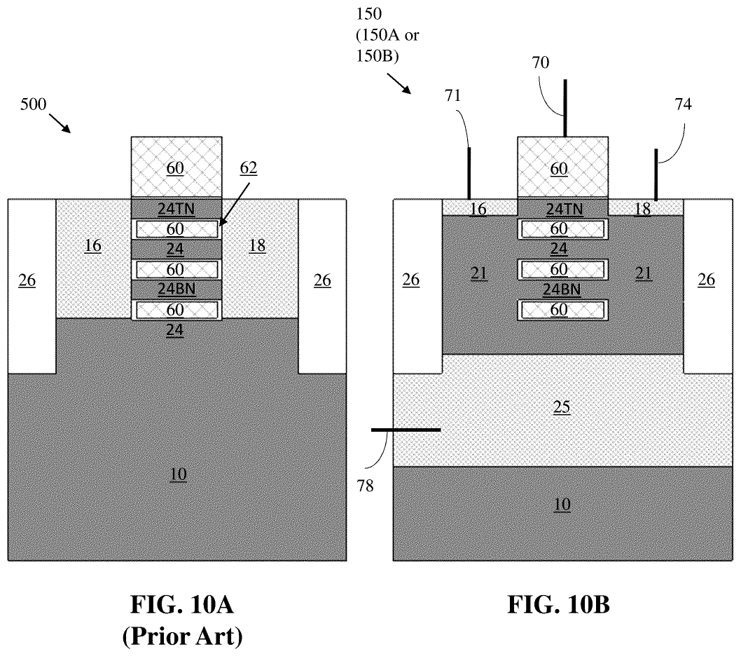

In another embodiment according to the present invention, a transistor such as nanosheet FET (e.g., see 50A, FIG. 2A), multi-bridge-channel (MBC) FET (e.g., see 50A, FIG. 2A), nanoribbon FET (e.g., see 50B, FIG. 2B), or nanowire FET (e.g., see 50B, FIG. 2B) can be used in a memory cell. For simplicity, they will collectively be referred to as gate-all-around (GAA) FET. FIG. 10A shows a cross-sectional view of a 3D structure 500 having a GAA FET configuration, cut along the gate length direction. Such cross-sectional view could be found in various prior arts such as U.S. Pat. Nos. 7,229,884 B2, 10,535,733 B2, 10,388,733, and 9,991,261. FIG. 10B shows a cross-sectional view of the memory cell 150 (memory cell 150A having nanosheet FET or MBC FET or memory cell 150B having nanoribbon FET or nanowire FET) according to an embodiment of the present invention. In the GAA FETs in FIGS. 10A and 10B, there are three floating body 24 or nanosheets or multi-bridge-channels or nanowires or nanoribbons 24 (for simplicity, they will be collectively referred to as nanosheets 24), which serve as a current conducting channels of the transistor formed by 16-24-18 surrounded by gate 60. The top most nanosheet 24 closest to the wafer front surface is referred to as the top nanosheet 24TN and the bottom most nanosheet 24 closest to the wafer back surface is referred to as the bottom nanosheet 24BN. In the GAA FET illustrated in FIG. 10A, the bottom junctions of the source region 16 and the drain region 18 are extended below to the bottom nanosheet 24. Therefore, the conduction current will flow in all three nanosheets when the transistors are turned on. In the memory cell 150A (having nanosheet FET or MBC FET) or 150B (having nanoribbon FET or nanowire FET) shown in FIG. 10B according to another embodiment of the present invention, the bottom junctions of the source region 16 and the drain region 18 are very shallow and only extend to the top nanosheet 24TN. Therefore, the conduction current for a turned-on state of the transistor of the memory cell 150A or 150B in FIG. 10B would be about one third of the conduction current for a turned on state of the GAA transistor 500 in FIG. 10A.

In one embodiment of the present invention, the known GAA FET shown in FIG. 10A for a generic logic circuit and the modified GAA FET for a memory cell shown in FIG. 10B are co-fabricated on the same wafer.

The low on-state current of the memory cell 150A or 150B can be used for the read current for logic-0 state. According to an embodiment of the present invention, when the memory cell 150 is in logic-1 state, the on-state current will be higher compared to when the memory cell 150 is in logic-0 state.

In order to achieve the bi-stable state, the memory cell 150a or 150B includes a buried well layer 25. The doping type of the buried well layer 25 may be identical to the doping type of the source and drain regions 16/18 but opposite to the doping type of the substrate 10. The top metallurgical junction of the buried well layer 25 or the top depletion boundary interface of the buried well layer 25 may overlap with the bottom of the insulating layer 26 (which may be STI).

The memory cell 150 as shown in FIG. 10B includes various control lines. The source region 16 is connected to source line (SL) terminal 71, the drain region 18 is connected to bit line terminal (BL) 74, the gate region 60 is connected to the word line (WL) terminal 70 and the buried well layer 25 is connected to the buried well line (BWL) terminal 78.

In order to distinguish from the nanosheet 24, the region between the source and drain regions 16/18 and the buried well layer 25 are specially referred to as floating base region 21. The region 21 of the memory cell 150 in FIG. 10B corresponds to the source and drain regions 16/18 of the GAA FET illustrated in FIG. 10A. The doping type of the floating base region 21 may be the same as the doping type of the nanosheet 24.

If floating base region 21 is neutrally charged, the memory cell 150 is in logic-0 state. If the floating base region 21 is positively charged, the memory cell 150 is in logic-1 state. As the insulating layer 26 extends into the buried well layer 25, the charged state of the floating base region 21 does not interfere with neighboring memory cells 150.

The hold, read, and write operations of the memory cell 150 comprising modified GAA FET are similar to the previous invention such as U.S. Pat. No. 8,077,536, “Method of Operating Semiconductor Memory Device with Floating Body Transistor Using Silicon Controlled Rectifier Principle”, U.S. Pat. No. 9,230,651, “Memory Device Having Electrically Floating Body Transistor”.

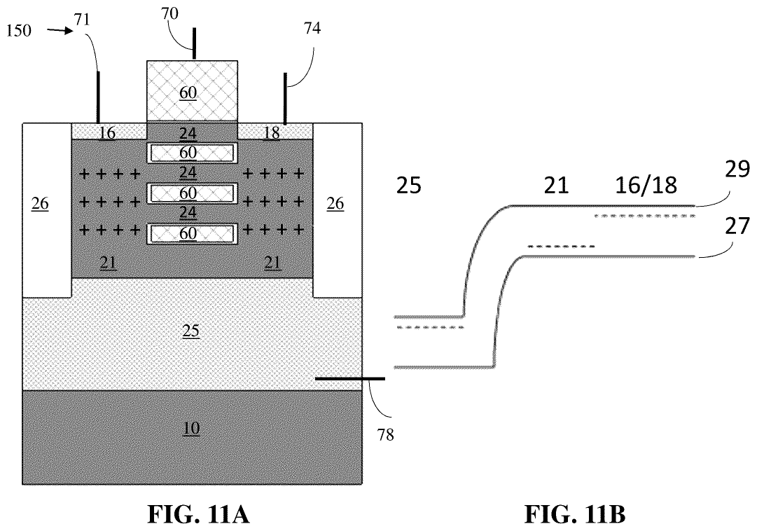

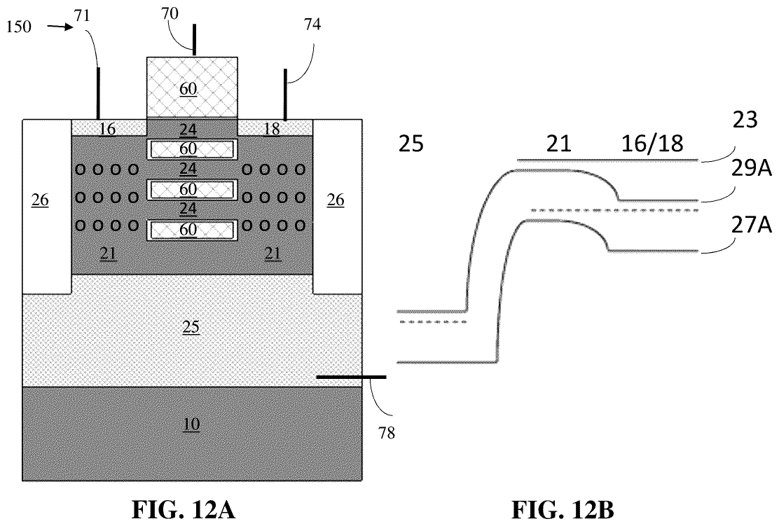

FIGS. 11A and 12A show the memory cell 150 having floating base region 21 and buried well layer 25 for representing the logic-1 and the logic-0 states, respectively. Vertical bipolar devices are inherently formed by the source/drain 16/18 regions, floating base region 21, and the buried well layer 25. FIG. 11A illustrates the positively charged floating base region 21 corresponding to the logic-1 and FIG. 12A illustrates the neutrally charged floating base region 21 corresponding to the logic-0.

FIG. 11B shows the energy band diagram of the vertical bipolar device when the floating base region 21 is positively charged and a positive bias is applied to the buried well layer 25 connected to BWL terminal 78. The dashed lines indicate the Fermi levels in the various regions of the bipolar device. The Fermi level is located in the band gap between the solid line 27 indicating the top of the valence band (the bottom of the band gap) and the solid line 29 indicating the bottom of the conduction band (the top of the band gap) as is well known in the art. If floating base region 21 is positively charged, a state corresponding to logic-1, the vertical bipolar transistors will be turned on as the positive charge in the floating base region 21 lowers the energy barrier of electron flow into the base region because zero voltage is applied to the source and/or drain region 16/18 through SL and/or BL terminals 71/74. Once electrons are injected into the floating base region 21, the electrons will be swept into the buried well layer 25 due to the positive bias applied to the buried well layer 25. As a result of the positive bias applied to the buried well layer 25, electrons are accelerated and create additional hot carriers (hot hole and hot electron pairs) through an impact ionization mechanism. The resulting hot electrons flow into the BWL terminal 78 while the resulting hot holes will subsequently flow into the floating base region 21. As a result of a positive-feedback mechanism, this process maintains the charge (i.e. holes) stored in the floating base region 21 which will keep the n-p-n vertical bipolar transistors on for as long as a positive bias is applied to the buried well layer 25 through BWL terminal 78.

If floating base region 21 is neutrally charged, a state corresponding to logic-0, no current will flow through the vertical bipolar transistors. The bipolar devices will remain off and no impact ionization occurs. Consequently, memory cells 150 in the logic-0 state will remain in the logic-0 state.

FIG. 12B shows the energy band diagram of the vertical bipolar device when the floating base region 21 is neutrally charged and a positive voltage is applied to the buried well layer 25 connected to BWL terminal 78. In this state the energy level of the band gap bounded by solid lines 27A and 29A is different in the various regions of bipolar device. Because the potential of the floating base region 21 and the source region 16 is equal, the Fermi levels are constant, resulting in an energy barrier between the source region 16 and the floating base region 21. Solid line 23 indicates, for reference purposes, the energy barrier between the source region 16 and the floating base region 21. The energy barrier prevents electron flow from the source region 16 to the floating base region 21. Thus, the bipolar device will remain off.

The read operation of the memory cell 150 could utilize any sensing scheme known in the arts. The amount of charge stored in the floating base region 21 can be sensed by monitoring the cell current of the memory cell 150 by applying a positive voltage to the BL terminal 74 and the WL terminal 70. If memory cell 150 is in a logic-1 state having positive charge in the floating base region 21, the memory cell 150 will have a higher cell current from BL terminal 74 to SL terminal 71 because the positive charge in the floating base region 21 would turn-on the all three nanosheet lateral bipolar transistors. However, if memory cell 150 is in a logic-0 state, the memory cell will have a lower cell current because only the top nanosheet 24TN would partially contribute to the cell current through MOS transistor.

In other embodiments, different voltages may be applied to the various terminals of the memory cell 150 as a matter of design choice and the exemplary voltages described are not limiting in any way.

From the foregoing it can be seen that a memory cell having an electrically floating body has been described. While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope of the invention as claimed.

1. A semiconductor memory cell comprising:
a floating body region configured to be charged to a level indicative of a state of the memory cell;
a first region in electrical contact with said floating body region;
a second region in electrical contact with said floating body region and spaced apart from said first region;
a gate positioned between said first and second regions;
wherein said gate surrounds said floating body region on all sides;
a buried well layer in electrical contact with a portion of said floating body region; and
a substrate underlying said floating body region and said first and second regions;
wherein said floating body region is configured to have at least first and second stable states;
wherein an amount of cell current from said first region to said second region when said floating body region is in said first stable state is higher than an amount of cell current from said first region to said second region when said floating body region is in said second stable state.

2. The semiconductor memory cell of claim 1, wherein said floating body region comprises a nanosheet FET, a multi-bridge-channel (MBC) FET, a nanoribbon FET or a nanowire FET.

3. The semiconductor memory cell of claim 1, wherein said floating body region is oriented vertically.

4. The semiconductor memory cell of claim 1, wherein a conduction pathway for current flow through the floating body region between the first and second regions is larger when said floating body region is in said first stable state than when said floating body region is in said second stable state.

5. The semiconductor memory cell of claim 1, wherein a number of conduction channels for current flow through the floating body region between the first and second regions when said floating body region is in said first stable state is greater than a number of conduction channels for current flow through the floating body region between the first and second regions when said floating body region is in said second stable state.

6. A semiconductor memory array, including:
a plurality of semiconductor memory cells as recited in claim 1, arranged in a matrix of rows and columns.

7. A method of operating a semiconductor memory cell having a floating body region configured to be charged to a level indicative of a state of the memory cell; a first region in electrical contact with said floating body region; a second region in electrical contact with said floating body region and spaced apart from said first region; a buried well layer in electrical contact with a portion of the floating body region; a gate positioned between said first and second regions; and a substrate underlying said floating body region and said first and second regions, wherein said gate surrounds said floating body region on all sides; said method comprising:
operating the semiconductor memory cell with the floating body region in a first stable state; and
operating the semiconductor memory cell with the floating body region in a second stable state;
wherein an amount of cell current from the first region to the second region when the floating body region is in the first stable state is higher than an amount of cell current from the first region to the second region when the floating body region is in the second stable state.

8. The method of claim 7, wherein the floating body region comprises a nanosheet FET, a multi-bridge-channel (MBC) FET, a nanoribbon FET or a nanowire FET.

9. The method of claim 7, wherein the floating body region is oriented vertically.

10. The method of claim 7, wherein a conduction pathway for current flow through the floating body region between the first and second regions is larger when said floating body region is in said first stable state than when said floating body region is in said second stable state.

11. The method of claim 7, wherein a number of conduction channels for current flow through the floating body region between the first and second regions when said floating body region is in said first stable state is greater than a number of conduction channels for current flow through the floating body region between the first and second regions when said floating body region is in said second stable state.

12. A memory cell comprising:
a semiconductor memory device comprising:
a first floating body region configured to be charged to a level indicative of a state of the memory cell;
a first region in electrical contact with said first floating body region;
a second region in electrical contact with said first floating body region and spaced apart from said first region; and
a first gate positioned between said first and second regions;
an access device comprising:
a second floating body region;
a third region in electrical contact with said second floating body region;
a fourth region is electrical contact with said second floating body region; and
a substrate underlying said semiconductor memory device and said access device;
wherein said semiconductor memory device and said access device are electrically connected in series; and
wherein at least one of said first gate and second gate surrounds at least one of said first floating body region and said second floating body region, respectively, on all sides.

13. The memory cell of claim 12, wherein at least one of said first floating body region and second floating body region comprises a nanosheet FET, a multi-bridge-channel (MBC) FET, a nanoribbon FET or a nanowire FET.

14. The memory cell of claim 12, wherein at least one of said first floating body region and second floating body region is oriented vertically.

15. The memory cell of claim 12, wherein said first floating body region is configured to have at least first and second stable states;
wherein an amount of cell current from said first region to said second region when said first floating body region is in said first stable state is higher than an amount of cell current from said first region to said second region when said first floating body region is in said second stable state.

16. The memory cell of claim 12, wherein said second region and said third region are a common shared region.

17. The memory cell of claim 12, wherein said first floating body region comprises multiple floating channels through which current can be selectively conducted between said first and second regions.

18. The memory cell of claim 12, wherein said first gate has a first gate length and said second gate has a second gate length;
wherein said second gate length is greater than said first gate length so that a lower impact ionization rate and lower gain of a parasitic bipolar are formed by said third region, second floating body region and fourth region than by said first region, first floating body region and said second region, so that charges are self-sustained in said first floating body region, but are not self-sustained said second floating body region.

19. A semiconductor memory array, including:
a plurality of semiconductor memory cells as recited in claim 12, arranged in a matrix of rows and columns.
